(19) United States
(12) Patent Application Publication
(10) Pub. No.: US 2014/0342473 A1
(43) Pub. Date: Nov. 20, 2014

(54) SEMICONDUCTOR PROCESSING METHOD

(71) Applicant: United Microelectronics Corp., Hsinchu (TW)

(72) Inventors: Sheng Zhang, Singapore (SG); Guang-You Yu, Singapore (SG); Ying-Jie Xu, Singapore (SG); Chaw Che, SINGAPORE (SG)

(73) Assignee: United Microelectronics Corp., Hsinchu (TW)

(21) Appl. No.: 13/894,031

(22) Filed: May 14, 2013

(51) Int. Cl. H01L 21/66

(52) U.S. Cl. CPC H01L 22/12
USPC 438/14

(57) ABSTRACT

A method for detecting metal contamination from a film-forming process causing interface traps is described. The film-forming process is performed to form a dielectric film on a wafer. An annealing treatment is performed to reduce the interface traps between the wafer and the dielectric film. Thereafter, the bulk recombination lifetime (BRLT) of the wafer is measured to estimate the amount of the metal contamination.

### BACKGROUND OF THE INVENTION

1. Field of Invention

This invention relates to a semiconductor processing method, and particularly relates to a method for detecting metal contamination from a film-forming process causing interface traps.

2. Description of Related Art

Metal contamination in a semiconductor wafer may be detected by measuring the bulk recombination lifetime (BRLT) of the wafer, because the metal species facilitates the recombination of electrons and holes. When the amount of metal contamination of the wafer is larger, the BRLT of the wafer is shorter. Accordingly, the amount of the metal contamination from an IC process can be detected by subjecting a wafer to the IC process and then measuring the BRLT of the wafer.

However, in cases that the wafer has been subjected to a film-forming process causing interface traps, the electron-hole recombination is significantly facilitated by the interface traps, and the BRLT of the wafer is short (<700 μsec) regardless of the metal contamination amount. Hence, the metal contamination from the film-forming process is difficult to detect based on the BRLT measurement of the wafer.

### SUMMARY OF THE INVENTION

In view of the foregoing, this invention provides a semiconductor processing method that is capable of reducing interface traps after a film-forming process.

This invention also provides, as an exemplary embodiment of the semiconductor processing method, a method for detecting metal contamination from a film-forming process causing interface traps.

In the detecting method of this invention, the film-forming process is performed to form a dielectric film on a wafer, an annealing treatment is performed to reduce the interface traps between the wafer and the dielectric film, and then the bulk recombination lifetime (BRLT) of the wafer is measured to estimate the amount of the metal contamination.

Because the density of interface traps (Dit) is significantly decreased due to the annealing treatment, the affect of the interface traps to the BRLT measurement is significantly reduced so that the metal contamination is detectable based on the BRLT.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A-1C and 2 illustrate a method for detecting metal contamination from a film-forming process causing interface traps according to an embodiment of this invention.

FIG. 3 shows the effect of the annealing treatment in the detection method to the reduction of the interface trap density (Dit) in an example of this invention.

FIG. 4 shows the effect of the annealing treatment in the detection method to the increase of the BRLT in the example of this invention.

### DESCRIPTION OF EMBODIMENT

It is noted that the following embodiment is intended to further explain this invention but not to limit the scope thereof. For example, although in the embodiment a wafer is used and is intended to investigate the metal contamination from the film-forming process, other kind of semiconductor wafer or substrate that has been subjected to a film-forming process causing interface traps may also be treated with the method of this invention, in which the density of interface traps is reduced by the annealing treatment in the method of this invention.

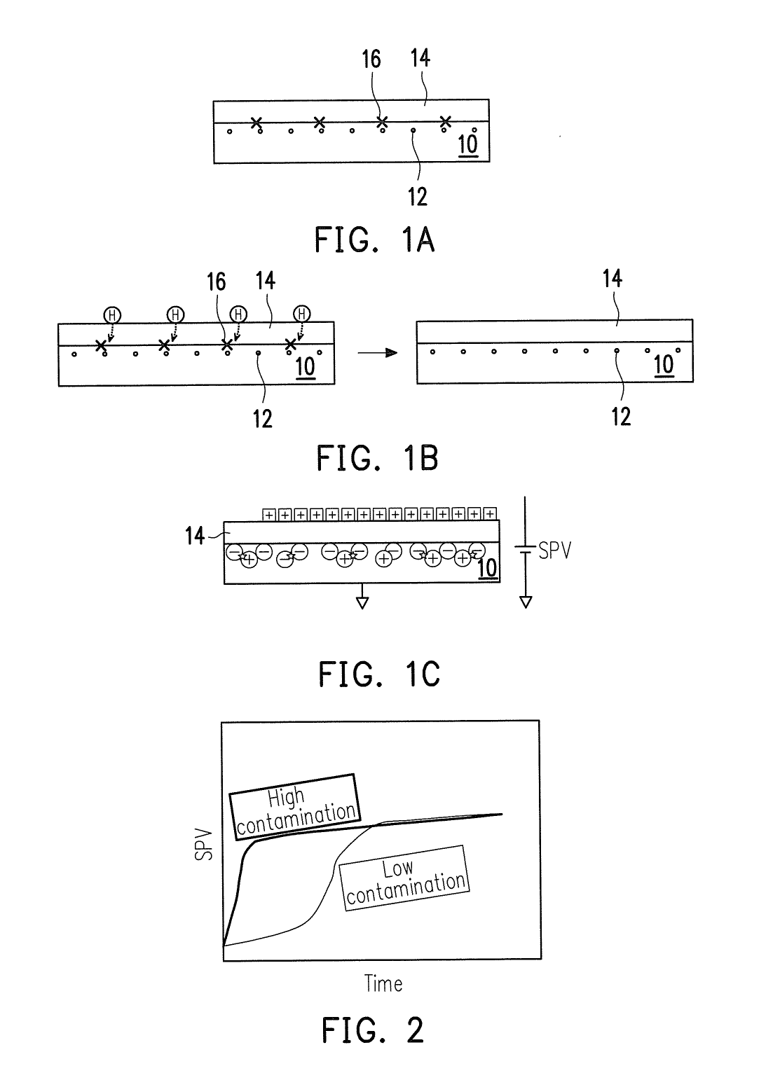

FIGS. 1A-1C and 2 illustrate a method for detecting metal contamination from a film-forming process causing interface traps according to an embodiment of this invention, wherein FIGS. 1C and 2 illustrate the BRLT measurement step in the method.

Referring to FIG. 1A, a wafer 10 is provided, which may include single-crystal silicon lightly doped with a p-dopant. A film-forming process causing interface traps is then performed to form a dielectric film 14 on the wafer 10, wherein metal contamination 12 is diffused into the wafer 10, and interface traps 16 are formed at the interface between the wafer 10 and the dielectric film 14.

The film-forming process may be a rapid thermal process (RTP), a high-density plasma chemical vapor deposition (HDP-CVD) process, or a LPCVD process. The LPCVD process may be carried out in a SINGEN™ system of Applied Materials, Inc. The rapid thermal process (RTP) may be a rapid thermal oxidation (RTO) process, which may cause metal contamination because of parts quality issue or damage. The dielectric film 14 may include silicon oxide, silicon nitride, or silicon oxynitride.

Referring to FIG. 1B, an annealing treatment is performed to reduce the interface traps 16 between the wafer 10 and the dielectric film 14. The annealing treatment preferably utilizes a gas containing at least one of H₂, N₂O and NO, while a case of using a H₂-containing gas is shown in FIG. 1B as an example. The annealing treatment is performed at 1000° C. to 1150° C. for 30 to 60 seconds, for example.

Referring to FIG. 1C, the bulk recombination lifetime (BRLT) of the wafer 10 is measured to estimate the amount of the metal contamination therein. The method for measuring the BRLT is disclosed in, for example, Dieter K. Schroder, “Contactless surface charge semiconductor characterization”, Materials Science and Engineering B91-92 (2002) 196-210. When a p-type wafer is used, for example, the method may include inducing an n-channel with corona on the surface of the wafer, light-irradiating the wafer (with a Xe lamp, for example) to create majority carriers (holes), and then, as shown in FIG. 1C, turning off the light and see how quickly the surface photo-voltage (SPV) of the wafer 10 decays due to the recombination of electrons and holes. As shown in FIG. 2, when the metal contamination amount is more, the SPC takes a shorter time to reach a constant-slope region, i.e., the BRLT is shorter. Such detection of metal contamination is possible because the density of the interface traps significantly facilitating the electron-hole recombination has been greatly reduced.

Based on the determination of the amount of metal contamination in the wafer with the above steps, the operator of the semiconductor manufacturing process is able to, for example, adjust the condition of the film-forming process to reduce the metal contamination of the subsequent work wafers.

To demonstrate the effects of this invention, an experiment example is described below. A certain number of control Si-wafers were each subjected to a rapid thermal oxidation (RTO) process using H₂ and O₂ at 1050° C. for 60 seconds, so that a thermal oxide film having a thickness of about 15 nm was formed on each sample wafer. The subsequent annealing treatment was performed with H₂ gas, under a pressure of 20 Torr at 1000° C. for 30 seconds. The BRLT measurement was according to the aforementioned reference.

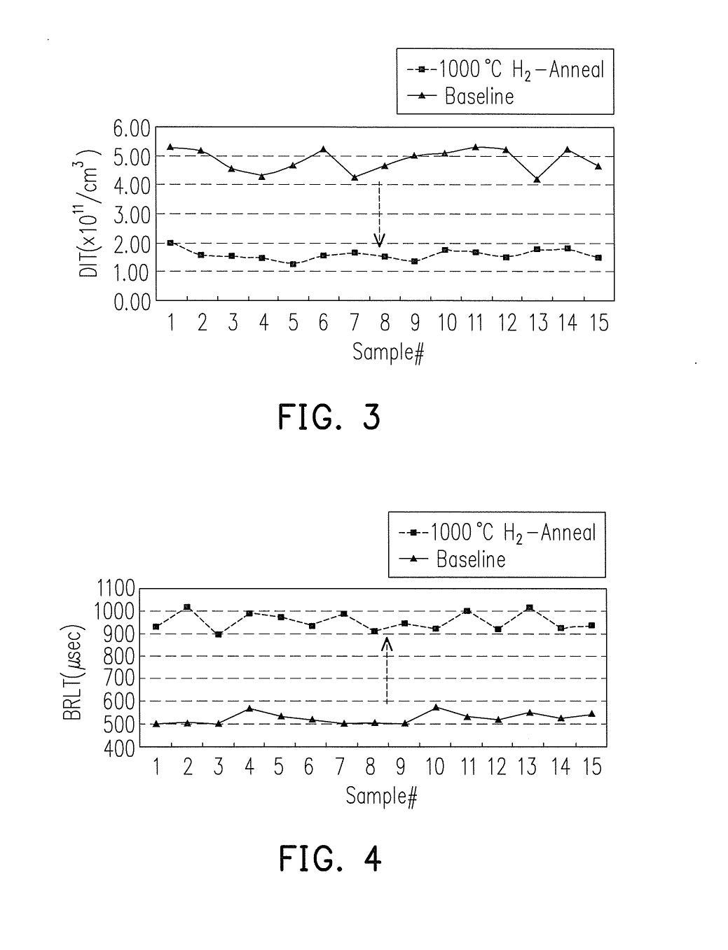

The result of the experiment example is shown in FIGS. 3-4 and Table 1, wherein FIG. 3 shows the effect of the annealing treatment to the reduction of the interface trap density (Dit), and FIG. 4 shows the effect of the annealing treatment to the increase of the BRLT.

TABLE 1

| Status | EOT (Å) | Dit (/cm³) | BRLT (μsec) |
|---|---|---|---|
| After RTO | 140-150 | 4.5-5.0 × 10¹¹ | <700 |
| After H₂-Anneal | 130-140 | 1.0-2.0 × 10¹¹ | >800 |

It is clear from FIGS. 3-4 and Table 1 that the method of this invention allows the Dit to be much reduced so that the BRLT of any sample is more than 800 μsec, which is considered as a lower limit of BRLT for successful application of the BRLT technique to the detection of metal contamination.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A method for detecting metal contamination from a film-forming process causing interface traps, comprising:
performing the film-forming process to form a dielectric film on a wafer;
performing an annealing treatment to reduce interface traps between the wafer and the dielectric film; and
measuring a bulk recombination lifetime (BRLT) of the wafer to estimate an amount of the metal contamination.

2. The method of claim 1, wherein the annealing treatment utilizes a gas containing at least one of H₂, N₂O and NO.

3. The method of claim 2, wherein the annealing treatment is performed at 1000° C. or higher for 30 to 60 seconds.

4. The method of claim 1, wherein the dielectric film comprises silicon oxide, silicon nitride, or silicon oxynitride.

5. The method of claim 1, wherein the film-forming process comprises a rapid thermal process (RTP), a high-density plasma chemical vapor deposition (HDP-CVD) process, or a LPCVD process.

6. A semiconductor processing method, comprising:
performing a film-forming process to form a dielectric film on a semiconductor substrate; and
performing an annealing treatment to reduce interface traps between the substrate and the dielectric film, wherein the annealing treatment utilizes a gas containing at least one of H₂, N₂O and NO.

7. The semiconductor processing method of claim 6, further comprising: measuring a bulk recombination lifetime (BRLT) of the substrate to estimate an amount of metal contamination therein.

8. The semiconductor processing method of claim 6, wherein the annealing treatment is performed at 1000° C. or higher for 30 to 60 seconds.

9. The semiconductor processing method of claim 6, wherein the dielectric film comprises silicon oxide, silicon nitride, or silicon oxynitride.

10. The semiconductor processing method of claim 6, wherein the film-forming process comprises a rapid thermal process (RTP), a high-density plasma chemical vapor deposition (HDP-CVD) process, or a LPCVD process.
